(19) United States
(12) Patent Application Publication
(10) Pub. No.: US 2025/0240873 A1
(43) Pub. Date: Jul. 24, 2025

(54) MULTI-LAMINATION STRUCTURE THAT ELIMINATES MICRO CAVITY RESONANCE

(71) Applicant: Cisco Technology, Inc., San Jose, CA (US)

(72) Inventors: Wenbin Ma, Shanghai (CN); Weiying Ding, Shanghai (CN); Mike Sapozhnikov, San Jose, CA (US); David Nozadze, San Jose, CA (US); Joel Richard Goergen, Soulsbyville, CA (US); Yuqing Zhu, Shanghai (CN); Mingtong Zuo, Shanghai (CN)

(21) Appl. No.: 18/417,844

(22) Filed: Jan. 19, 2024

(51) Int. Cl. H05K 1/02; H05K 1/11

(52) U.S. Cl. CPC H05K 1/0228; H05K 1/115; H05K 2201/09609

(57) ABSTRACT

A multi-lamination stack up structure that separates high speed routing and the power delivery plane. The multi-lamination stack up structure includes M+N layers. The M layers are located on the top of the PCB and focus on high speed design routing. The N layers are located on the bottom of the PCB and are used for the power plane. In one implementation, the PCB uses a through hole or VIA for M+N layers power connection at the chip ball grid array area.

### TECHNICAL FIELD

The present disclosure relates to circuit boards and, more particularly, to circuit boards that have a multi-lamination structure.

### BACKGROUND

For a high power and dense system, it is very challenging to design the system so that it has satisfactory signal integrity to achieve the best performance of insertion loss, reflections, and crosstalk. In addition, power integrity is very challenging because the power plane shape is shrunken and broken with more stitching VIAs to try to optimize crosstalk performance.

For a 224 Gbps high density application specific integrated circuit (ASIC), a 102.4T switch has 512 lanes of 224 Gbps SerDes and power consumption more than 1200 W. The package size will be above 95 mm×95 mm, and a lower pitch (approximately 0.9 mm) may be needed due to manufacturing concerns of solderability and coplanarity.

A related art design uses one lamination stack up and advanced PCB technology such as a high-density interconnect (HDI) process. For a 102.4T system, there may need to be around 44 layers in the stack up, such as 10 power layers for high current power and two lower current power layers, as well as 12 high speed routing layers and two miscellaneous layers. The resulting board thickness is around 210 mm.

Crosstalk, including both far-end crosstalk (FEXT) and near end crosstalk (NEXT), is difficult to manage since power planes are broken by a large quantity of ground VIAs, which cut up power planes. Power planes with large cut outs introduce micro cavity resonance to the signals. The cavity resonance causes a significant negative impact on crosstalk. Some specifical frequency energy levels do not propagate but oscillate back and forth in the form of standing-waves, which degrade crosstalk performance dramatically. This issue is exacerbated further by the manufacturing tolerances related to the layer-to-layer misregistration and the drill position misregistration. The other challenges are the overall board thickness and the aspect ratio for the VIA drills as the VIA structure process (the HDI PCB process) cannot be skipped due to the manufacturing constraints and overall PCB cost.

### BRIEF DESCRIPTION OF THE DRAWINGS

FIG. 1 is a schematic diagram of an example embodiment of a PCB, according to the techniques disclosed herein.

FIG. 2 is a perspective view of a related art PCB.

FIG. 3 is a side view of another related art PCB.

FIG. 4 is a side view of another related art PCB.

FIG. 5 is a top view of a power plane of a related art PCB.

FIG. 6 is an exploded perspective view of an example embodiment of a PCB, according to the techniques disclosed herein.

FIG. 7 is a side view of another example embodiment of a PCB, according to the techniques disclosed herein.

FIG. 8A is a perspective view of an example embodiment of a related art PCB.

FIG. 8B is a side view of the PCB illustrated in FIG. 8A.

FIG. 8C is a top view of a layer of the PCB illustrated in FIG. 8A.

FIG. 9A is a perspective view of another example embodiment of a related art PCB.

FIG. 9B is a side view of the PCB illustrated in FIG. 9A.

FIG. 9C is a top view of a layer of the PCB illustrated in FIG. 9A.

FIG. 10A is a perspective view of another example embodiment of a PCB, according to the techniques disclosed herein.

FIG. 10B is a side view of the PCB illustrated in FIG. 10A.

FIG. 10C is a top view of a layer of the PCB illustrated in FIG. 10A.

FIG. 11A is a perspective view of another example embodiment of a PCB, according to the techniques disclosed herein.

FIG. 11B is a side view of the PCB illustrated in FIG. 11A.

FIG. 11C is a top view of a layer of the PCB illustrated in FIG. 11A.

FIG. 12 is a graph of crosstalk performance of NEXT signals in decibels associated with a related art PCB.

FIG. 13 is a graph of crosstalk performance of NEXT signals in decibels associated with a PCB implementing the disclosed techniques, according to an example embodiment.

FIG. 14 is a graph of crosstalk performance of FEXT signals in decibels associated with a related art PCB.

FIG. 15 is a graph of crosstalk performance of FEXT signals in decibels associated with a PCT implementing the disclosed techniques, according to an example embodiment.

### DETAILED DESCRIPTION

### Overview

The problems with related art PCBs are addressed by the techniques disclosed herein with minimum impact to the PCB thickness and cost. In one implementation, the disclosed techniques relate to a multi-lamination stack up structure that separates high speed routing and the power delivery plane. The multi-lamination stack up structure includes M+N layers. The M layers are located on the top of the PCB and focus on high speed design (HSD) routing. The N layers are located on the bottom of the PCB and are used for the power plane. In one implementation, the PCB uses a through hole or VIA for M+N layers power connection at the chip ball grid array (BGA) area. Because there are fewer VIAs and cutups of the power plane, the power plane is more uniform (from the voltage regulator module (VRM) to the chip load side) and does not have any cavity resonance. As a result, signal integrity crosstalk performance is good. In a PCB according to the disclosed techniques, there are no HSD VIAs blocking the power delivery shape and cutting up the power plane. The result is that power integrity and power performance for the PCB are improved.

The techniques described herein relate to a PCB with a multi-lamination structure that enables higher isolation for a high power and dense system. In one implementation, the PCB is used in a 224 Gbps signal system. In a 224 Gbps system, the design target is a power sum of near-end-crosstalk (PS-NEXT) below-55 db at 56 GHz and a power sum of FEXT (PS-FEXT) below-40 dB at 56 GHz.

### Example Embodiments

The techniques disclosed herein relate to a PCB with a multi-lamination structure that has two lamination structures, one of which relates to high speed routing and the other of which relates to power delivery. The integrity of the power delivery layers is improved because the quantity of cutouts and openings is greatly reduced, thereby resulting in better overall power delivery and performance.

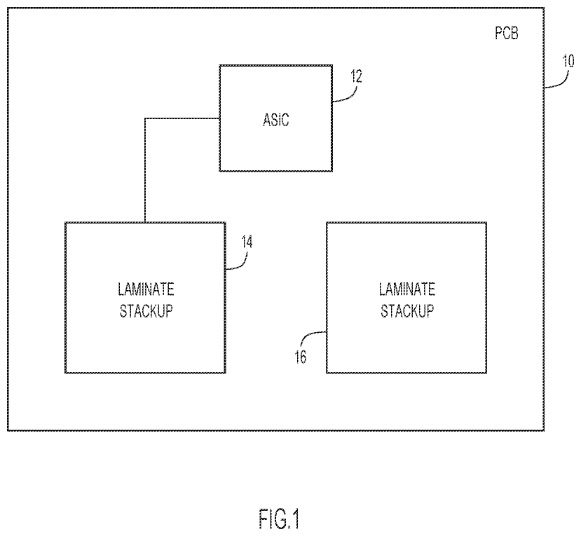

Turning to FIG. 1, a schematic view of an example embodiment of a PCB according to the techniques disclosed herein is illustrated. In this embodiment, the PCB 10 includes an ASIC 12 and two laminate stack ups 14 and 16. Laminate stack up 14 includes several layers that are laminated together. Laminate stack up 16 includes several layers that are laminated together. Once stack up 14 is laminated, and stack up 16 is laminated, the laminated stack ups 14 and 16 are laminated together. As described in more detail below, laminated stack up 14 is directed to high speed signal routing, and laminated stack up 16 is directed to delivering power.

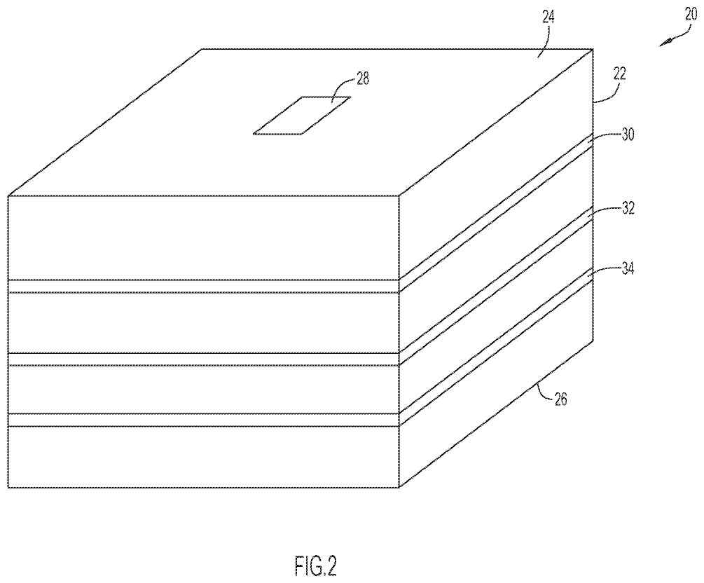

Referring to FIG. 2, a perspective view of an example embodiment of a related art PCB is illustrated. In this embodiment, the related art PCB 20 is formed of a laminated stack up 22 that is formed of several different layers. The laminated stack up 22 has an upper surface 24 and a lower surface 26 opposite the upper surface 24. An ASIC 28 is mounted to the upper surface 24. In this embodiment, the layers in the laminated stack up 22 includes several power layers 30, 32, and 34 that are spaced apart from each other along the stack up 22, as shown in FIG. 2.

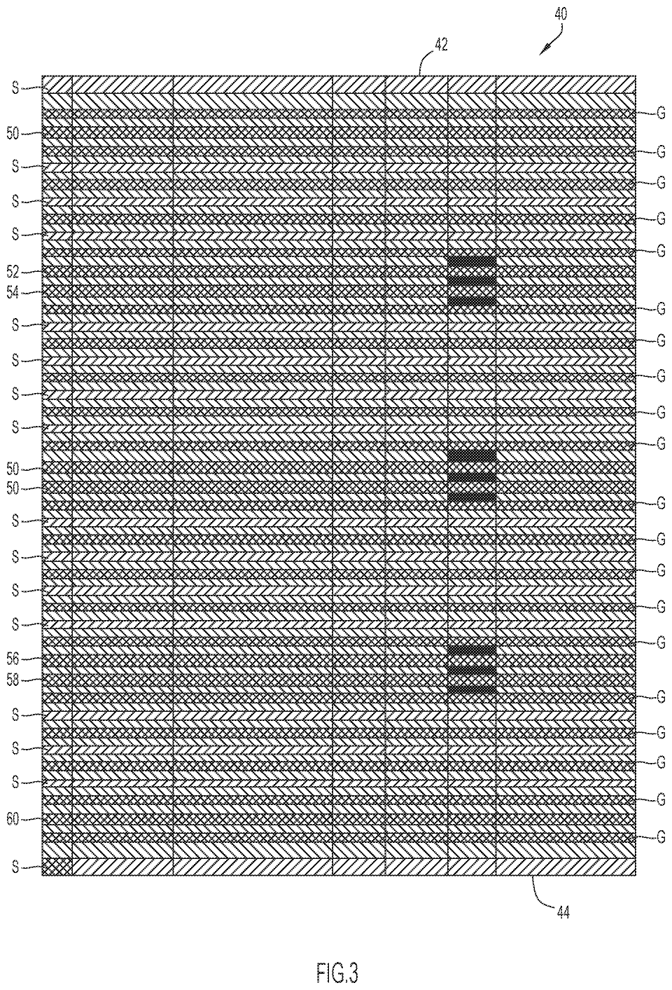

Referring to FIG. 3, a side view of an example embodiment of a related art PCB is illustrated. PCB 40 is an example of a related art PCB with 44 layers in a one-lamination stack up, which has a thickness of 209.2 mm. In this embodiment, the related art PCB 40 has an upper surface 42 and a lower surface 44 opposite to upper surface 42. The PCB 40 includes several ground layers, indicated by G, several signal layers, indicated by S, and several power layers 50, 52, 54, 56, and 58. The power layers 50, 52, 54, 56, and 58 are spaced apart and are in different portions of the PCB 40. In this embodiment, there are 16 signal layers and 20 ground layers.

Another option for manufacturing a PCB is using HDI techniques. HDI techniques are very expensive (i.e., one additional lamination increases costs by more than 50%). In one related art implementation, a PCB with 44 HDI layers, with 12 HSD routing layers, may need 11 laminations, which results in a huge additional cost (close to a 5.5 times increase). In addition, such a design is complex with one or more buried VIAs, blind VIAs, skip VIAs, stack VIAs, micro VIAs, and PHT VIAs. Also, there may be long-term reliability concerns with such a design, and a potential de-lamination risk if there are more than four laminations.

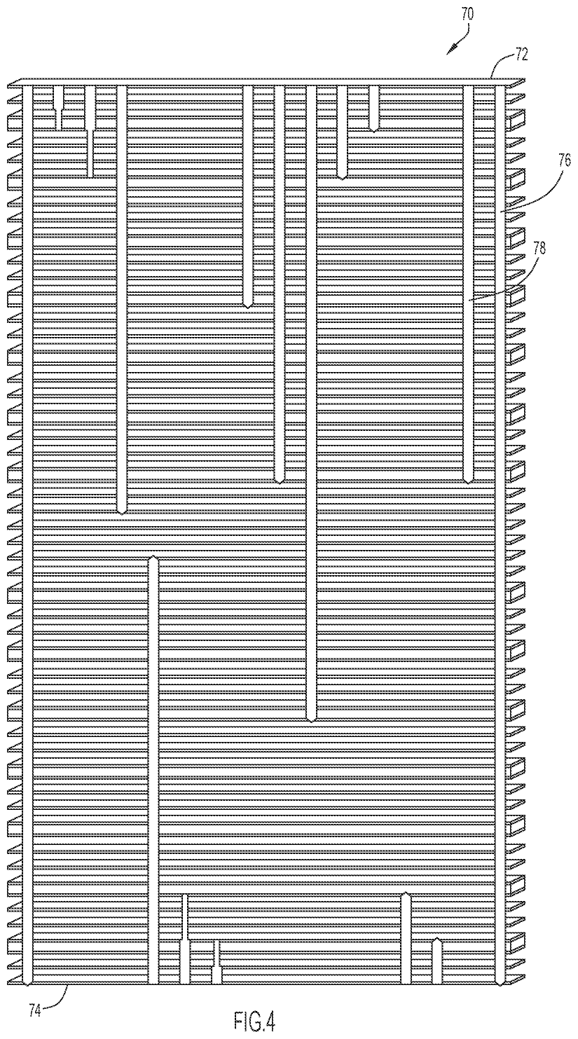

Referring to FIG. 4, a side view of another example embodiment of a related art PCB is illustrated. PCB 70 is an example of a related art PCB with 32 layers that is made using HDI techniques. PCB 70 needs multiple laminations and has several different types of micro VIAs. PCB 70 has an upper surface 72, an opposite lower surface 74, through VIAs 76, and other VIAs 78 formed therein.

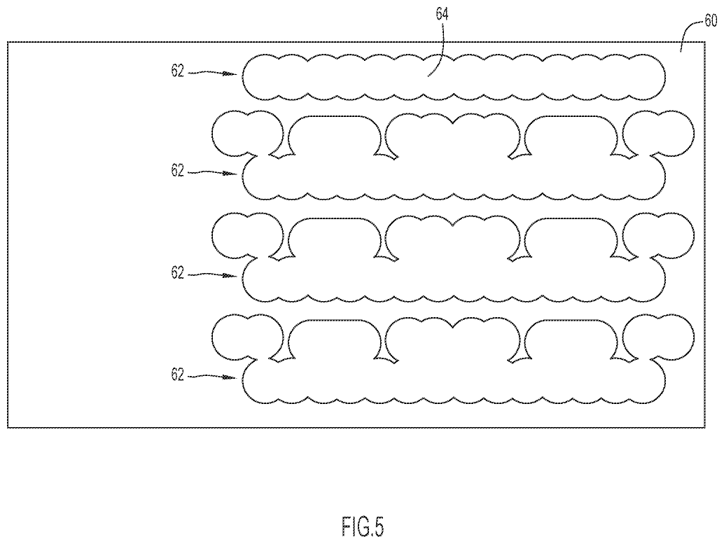

Referring to FIG. 5, a top view of an example embodiment of a power plane of a related art PCB is illustrated. The power plane 60 has a cavity structure 62 that includes multiple different cutouts or openings 64 formed therein. The vast quantity of openings 64, and the shapes thereof, interrupt the body of the power plane 60, which negatively affects and impairs the ability of the power plane 60 to deliver power for the PCB sufficiently.

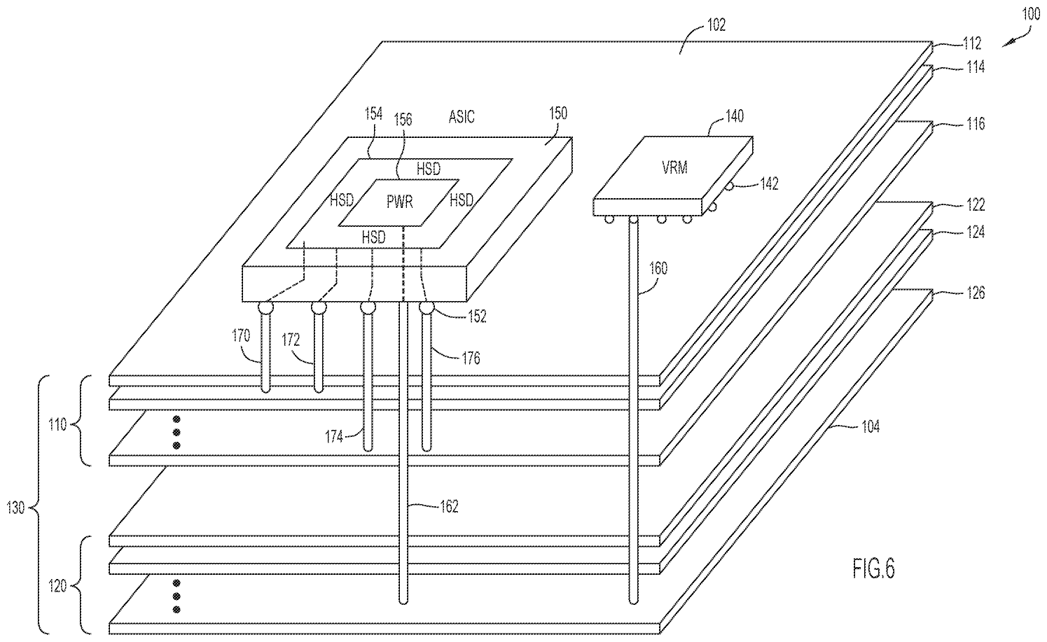

Turning now to FIG. 6, an exploded perspective view of an embodiment of a circuit board according to the disclosed techniques is illustrated. In this embodiment, PCB 100 has an upper surface 102 and an opposite lower surface 104. The PCB 100 includes a lamination structure or stack up 110 that is formed from a group or plurality of layers. While lamination structure 110 is illustrated with layers 112, 114, and 116, it is to be understood that there can be more layers in lamination structure 110, as noted by the ellipses. The PCB 100 includes another lamination structure or stack up 120 that is formed from another group or plurality of layers. While lamination structure 120 is illustrated with layers 122, 124, and 126, it is to be understood that there can be more layers in lamination structure 120, as noted by the ellipses.

A quantity of layers, including layers 112, 114, and 116, and others, is selected to form a group or plurality of layers, which are laminated together using a lamination process to form lamination structure or stack up 110. In one implementation, there are M layers in the lamination structure 110. The layers in lamination structure 110 are directed to carrying high speed routing signals for the PCB 100.

Another quantity of layers, including layers 122, 124, and 126, and others, is selected to form another group or plurality of layers, which are laminated together using a lamination process to form lamination structure or stack up 120. In one implementation, there are N layers in the lamination structure 120. In one embodiment, the quantity of M layers is larger than the quantity of N layers. In one example embodiment, the quantity of M layers is 24 layers and the quantity of N layers is 12 layers.

After lamination structure 110 is formed and after lamination structure 120 is formed, the two lamination structures 110 and 120 can be laminated together to form a multi-lamination structure 130. The resulting multi-lamination structure 130 has a first portion directed to high speed routing signals and a second portion directed to power delivery.

As shown in FIG. 6, the PCB 100 includes a VRM 140 that is connected to the upper surface 102 of the PCB 100 via connections that are part of a BGA 142. The VRM 140 is connected to the power layers by a power VIA 160 that extends through the first lamination structure 110 (the high speed routing signal layers) and through the second lamination structure 120 (the power layers) to the outer layer 126.

The PCB 100 also includes an ASIC 150 that is connected to the upper surface 102 of the PCB 100 via connections that are part of a BGA 152. The ASIC 150 includes an HSD portion 154 and a power portion 156. The HSD portion 154 is connected to different layers in the first lamination structure 110 by different VIAs 170, 172, 174, and 176, some of which may have different lengths. However, none of the VIAs 170, 172, 174, and 176 extends through or requires a cutout or opening to be formed in the power plane, or any of the layers of second lamination structure 120. The power portion 156 of the ASIC 150 is connected to the power layers by a power VIA 162 that extends through the first lamination structure 110 and through the second lamination structure 120 to the outer layer 126.

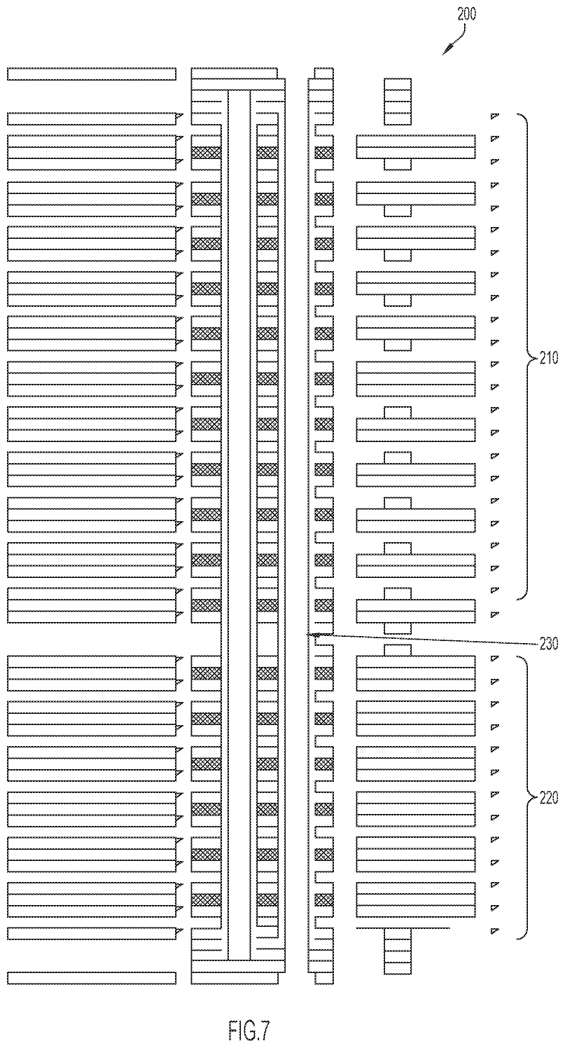

An example embodiment of a PCB according to the disclosed techniques is illustrated in FIG. 7. In this embodiment, PCB 200 includes a group or plurality of layers that are laminated together to form lamination structure 210. PCB 200 includes another group or plurality of layers that are laminated together to form lamination structure 220. The layers in lamination structure 210 are related to high speed signal routing, and the layers in lamination structure 220 are related to power delivery. In this embodiment, there are more layers in lamination structure 210 than there are layers in lamination structure 220. In one implementation, lamination structure 210 includes 24 layers and lamination structure 220 includes 12 layers. PCB 200 includes a through hole or VIA 230 that is used for the power connection of the lamination structures 210 and 220 at the BGA area and VRMs.

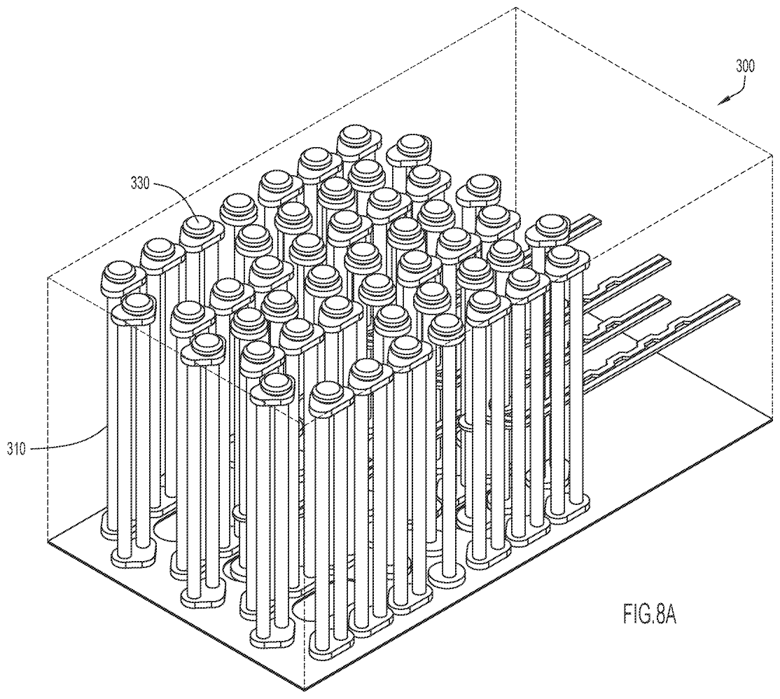

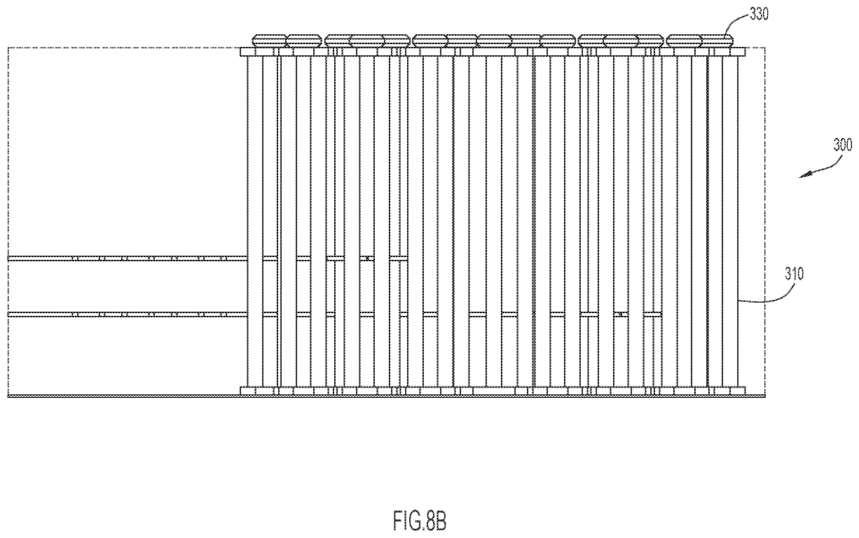

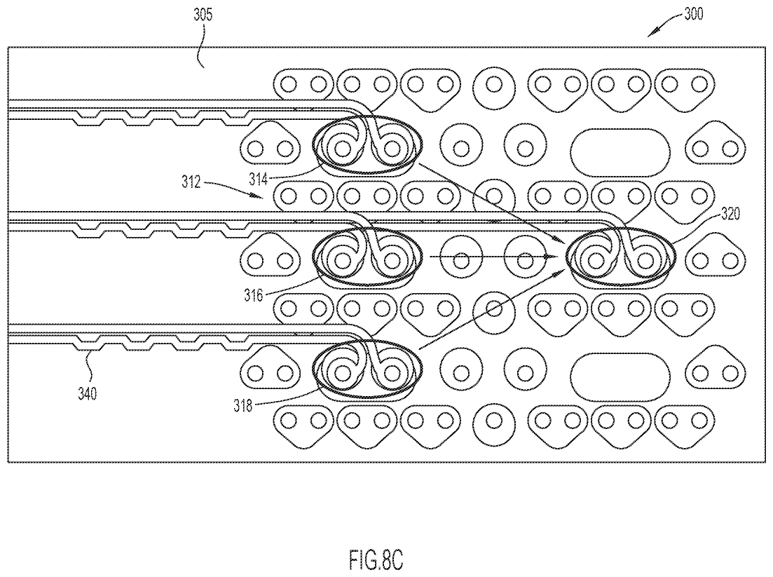

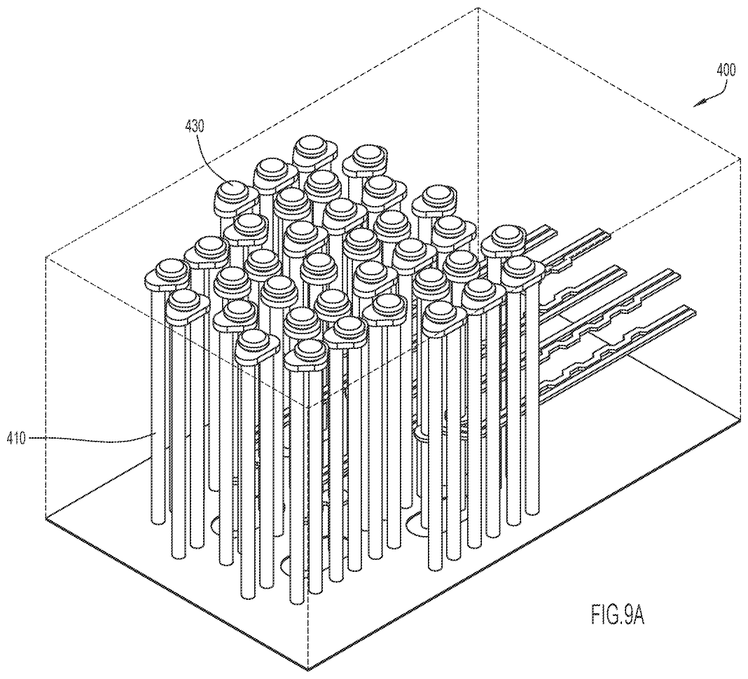

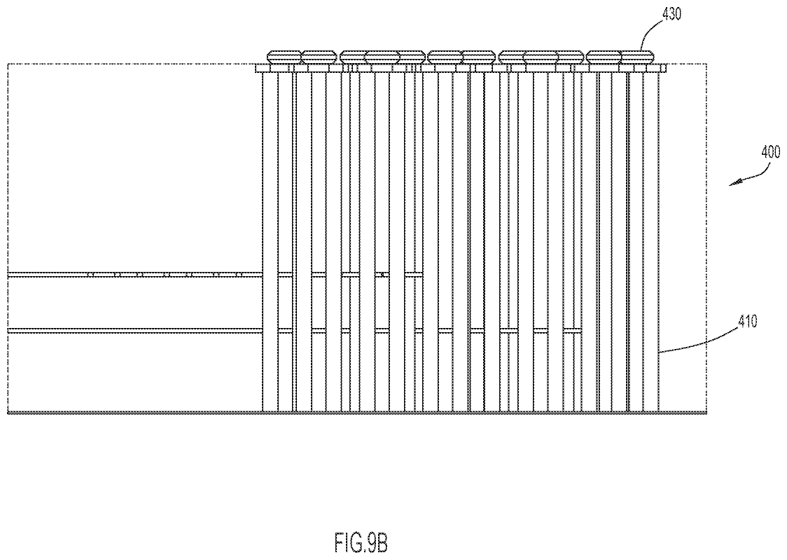

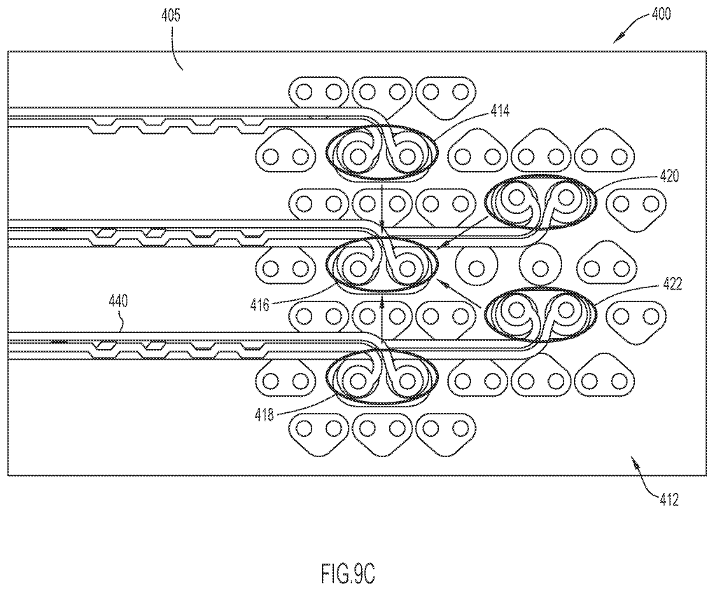

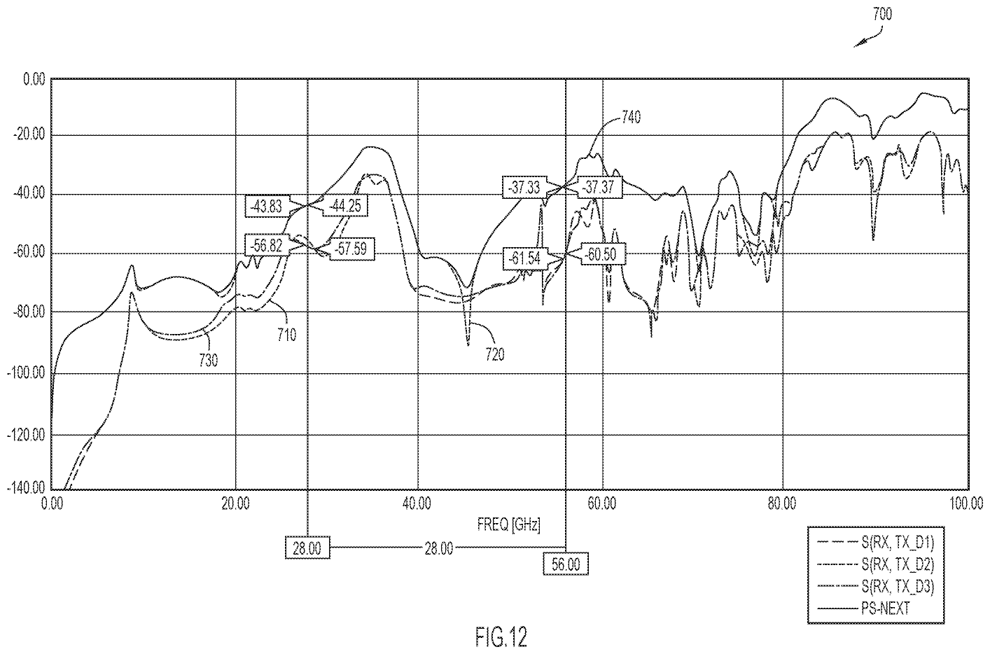

Turning to FIGS. 8A-9C, different views of related art PCB structures are illustrated. Referring initially to FIGS. 8A-8C, the related art PCB 300 includes several VIAs 310 and a BGA 330. As shown in layer 305, there are several traces 340 coupled to layer 305 that form different pairs 312 and are connected to VIAs. Differential pairs 314 (indicated by D1), 316 (indicated by D2), 318 (indicated by D3), and 320 are connected to different traces 340. In this implementation, each of the HSD pairs 314, 316, and 318 is an aggressor in terms of creating a disruption and negatively impacting the signal integrity for HSD pair 320. The NEXT performance of related art PCB 300 is illustrated in FIG. 12, which is described in detail below. In this embodiment, the transmission signal is on layer 31, the receiving signal is on layer 36, with 23.5 millimeter spacing between them. PCB 300 includes a floating power plane as well.

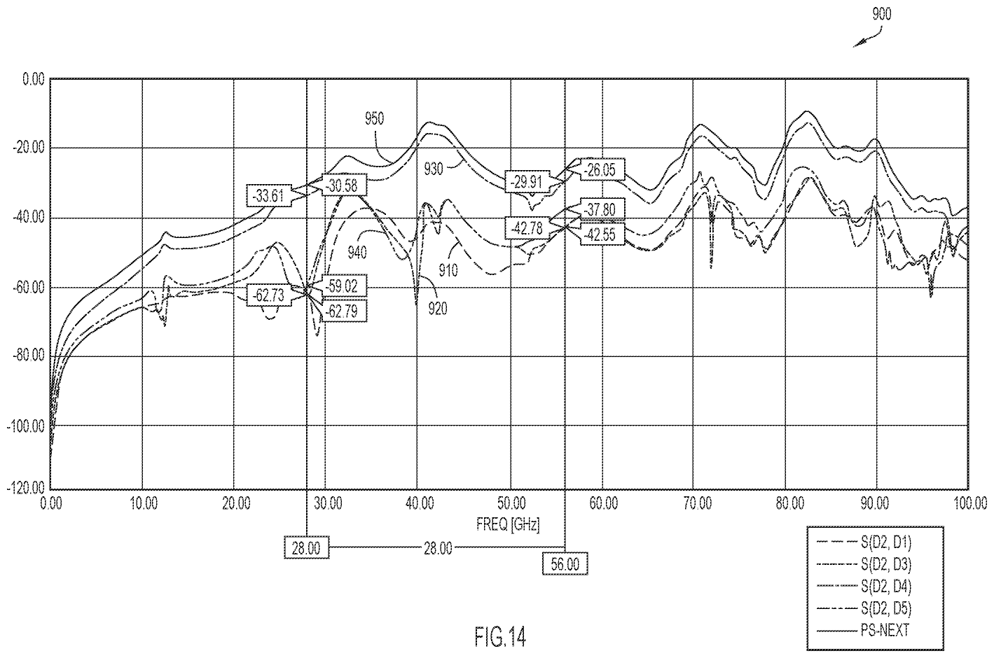

Referring initially to FIGS. 9A-9C, the related art PCB 400 includes several VIAs 410 and a BGA 430. As shown in layer 405, there are several traces 440 coupled to layer 405 that form different pairs 412 and are connected to VIAs. Differential pairs 414 (indicated by D1), 416 (indicated by D2), 418 (indicated by D3), 420 (indicated by D4), and 422 (indicated by D5) are connected to different traces 440. In this implementation, each of the HSD pairs 414, 418, 420, and 422 is an aggressor in terms of creating a disruption and negatively impacting the signal integrity for HSD pair 416. The FEXT performance of related art PCB 400 is illustrated in FIG. 14, which is described in detail below. In FIG. 9C, the notation “2×” indicates that there is another aggressor at a symmetrical position with the same crosstalk impact as this one. As a result, the FEXT calculation at that location is doubled. In this embodiment, the transmission signal is on layer 38, the receiving signal is on layer 40, with 8.7 millimeter spacing between them. PCB 400 includes a floating power plane as well.

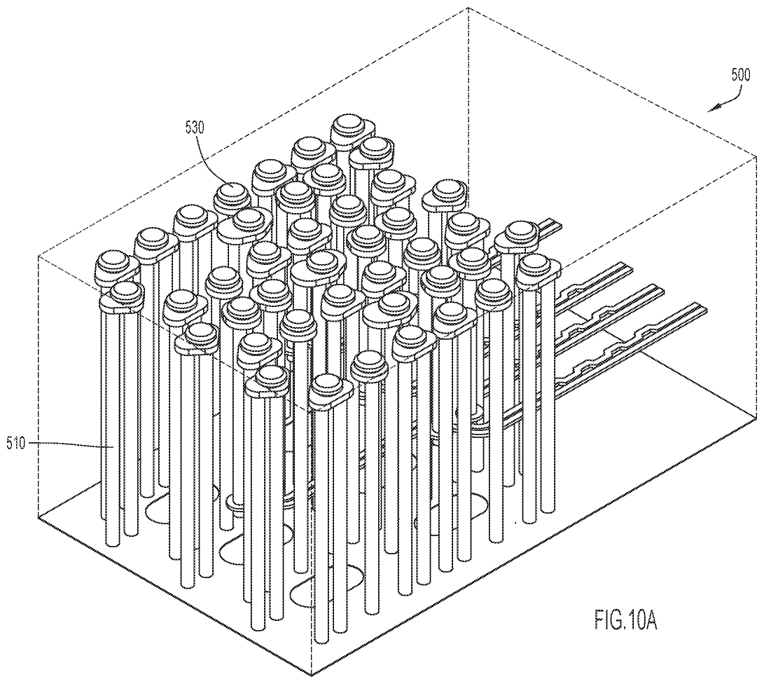

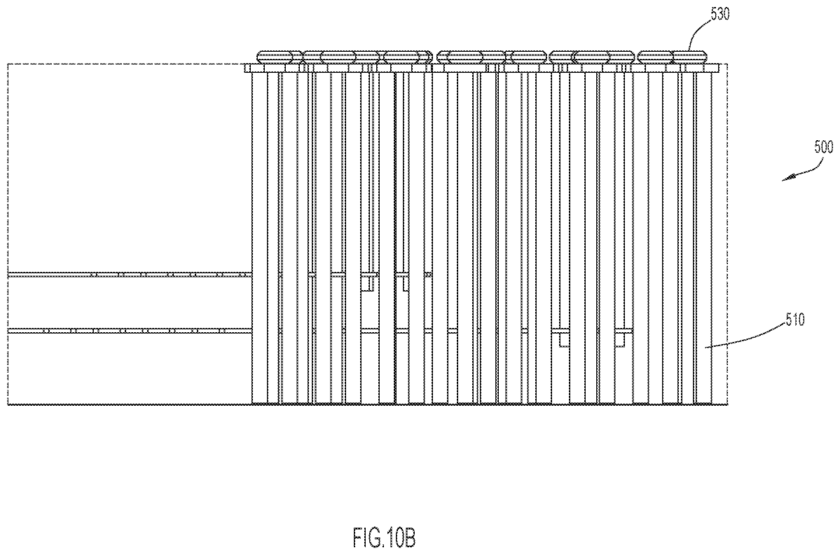

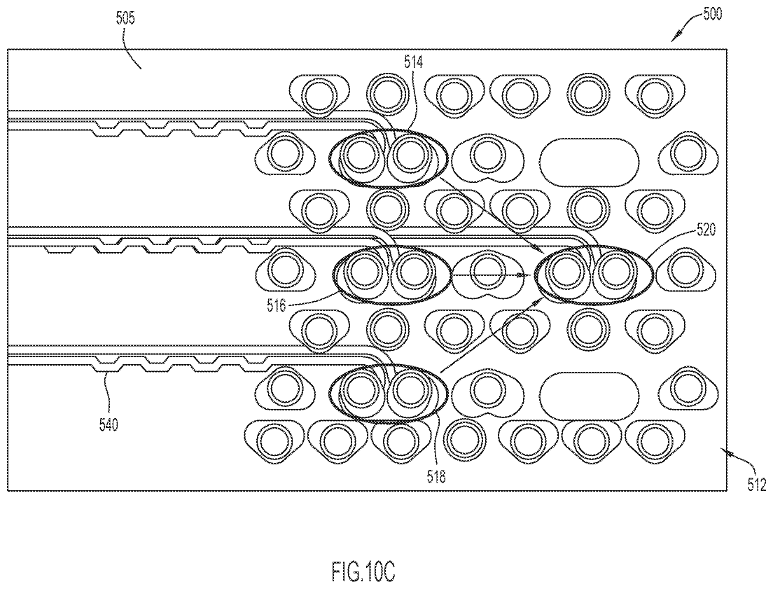

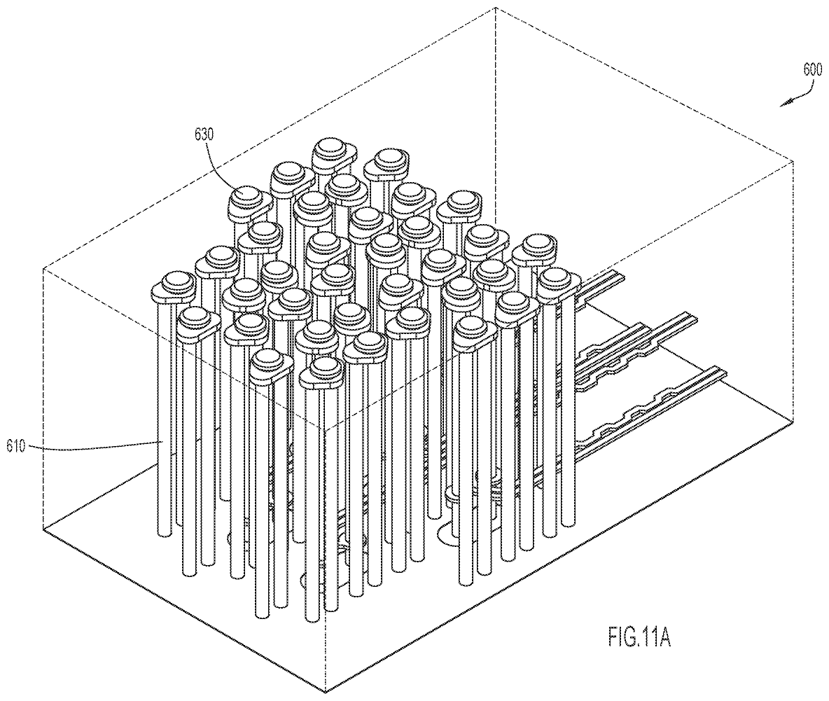

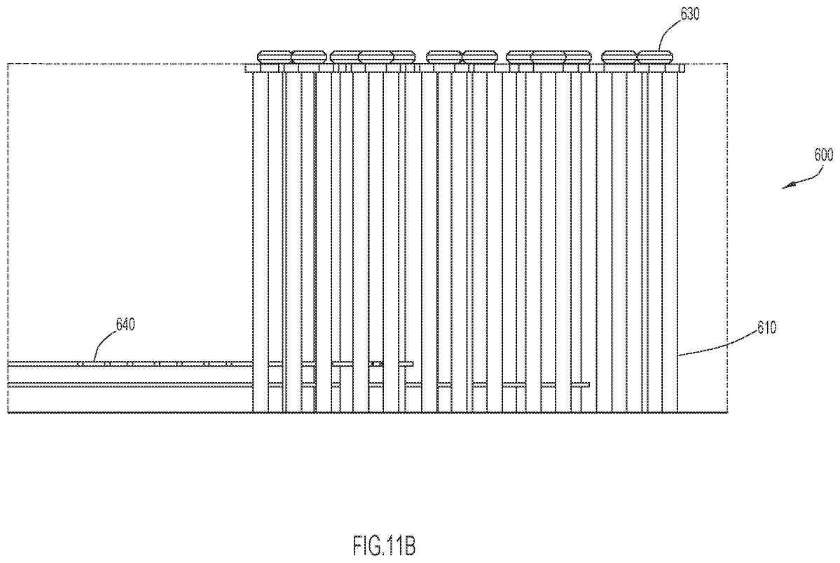

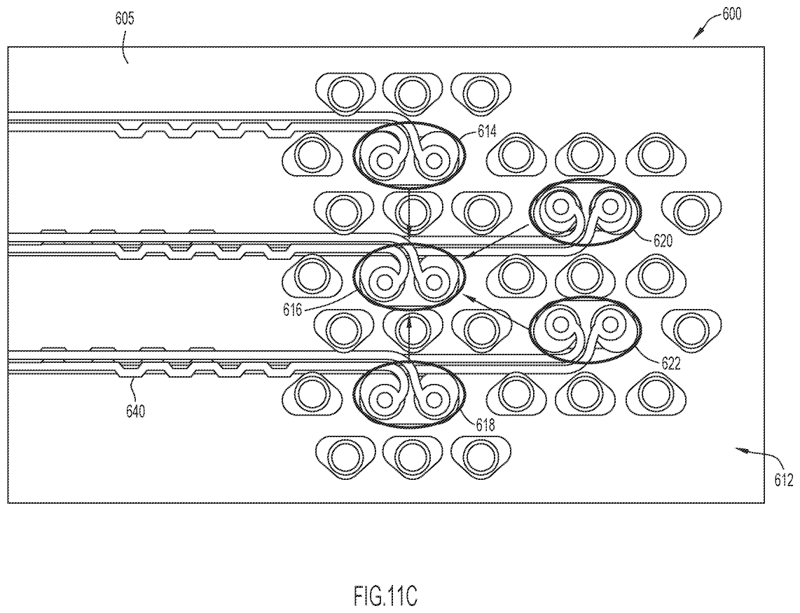

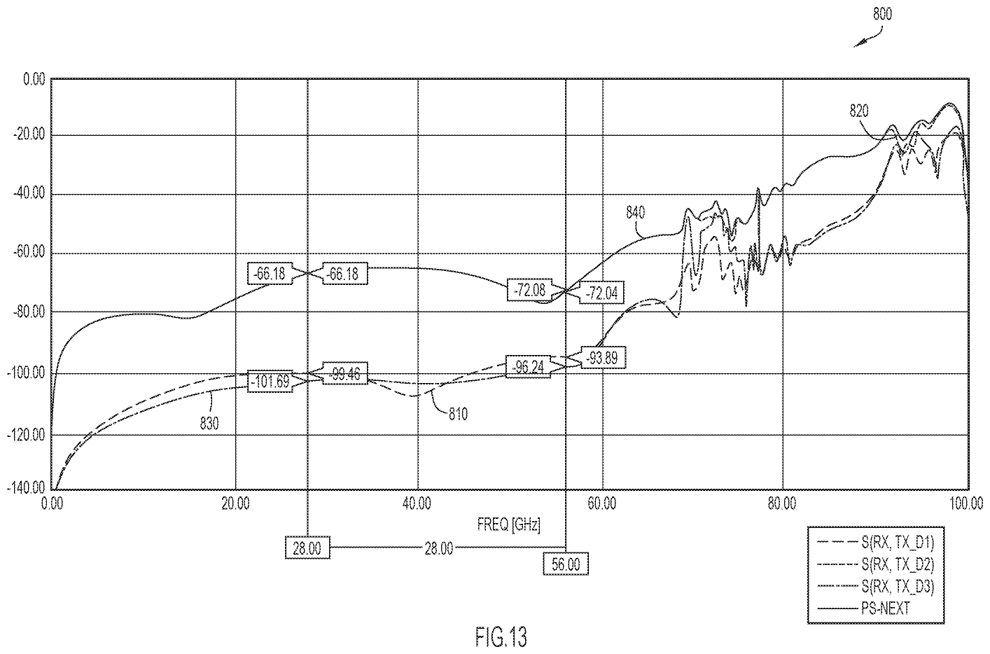

Turning to FIGS. 10A-11C, different views of PCB structures according to the disclosed techniques are illustrated. Referring initially to FIGS. 10A-10C, the PCB 500 includes several VIAs 510 and a BGA 530. As shown in layer 505, there are several traces 540 coupled to layer 505 that form different pairs 512 and are connected to VIAs. Differential pairs 514 (indicated by D1), 516 (indicated by D2), 518 (indicated by D3), and 520 are connected to different traces 540. In this implementation, each of the HSD pairs 514, 516, and 518 is an aggressor in terms of creating a disruption and negatively impacting the signal integrity for HSD pair 520. The NEXT performance of PCB 500 is illustrated in FIG. 13, which is described in detail below. In this embodiment, the transmission signal is on layer 11, the receiving signal is on layer 14, with 24 millimeter spacing between them.

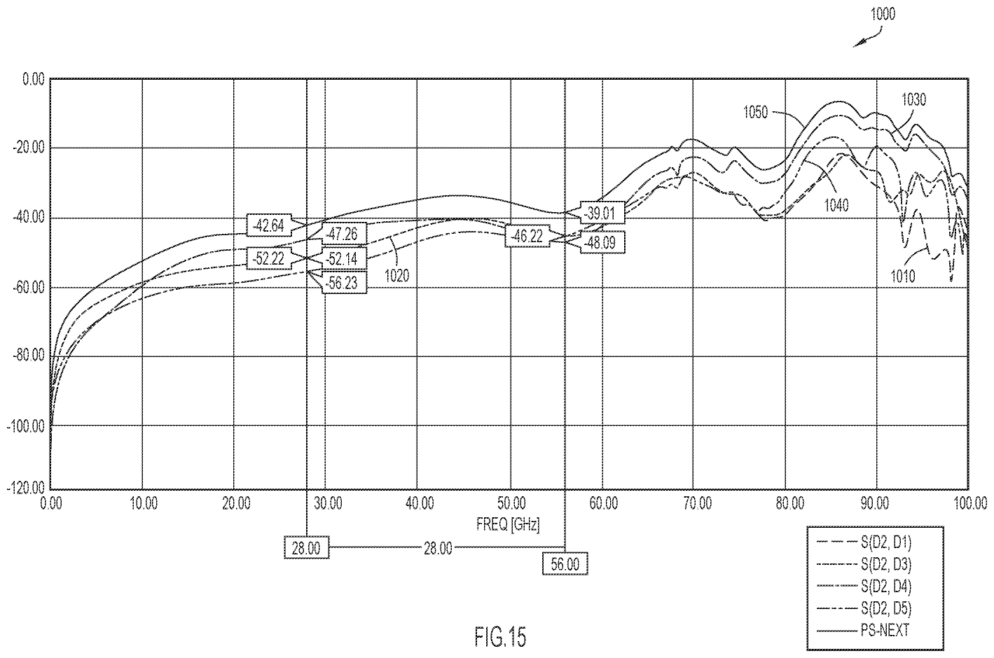

Referring initially to FIGS. 11A-11C, the PCB 600 includes several VIAs 610 and a BGA 630. As shown in layer 605, there are several traces 640 coupled to layer 605 that form different pairs 612 and are connected to VIAs. Differential pairs 614 (indicated by D1), 616 (indicated by D2), 618 (indicated by D3), 620 (indicated by D4), and 622 (indicated by D5) are connected to different traces 640. In this implementation, each of the HSD pairs 614, 618, 620, and 622 is an aggressor in terms of creating a disruption and negatively impacting the signal integrity for HSD pair 616. The FEXT performance of PCB 600 is illustrated in FIG. 15, which is described in detail below. In FIG. 11C, the notation “2×” indicates that there is another aggressor at a symmetrical position with the same crosstalk impact as this one. As a result, the FEXT calculation at that location is doubled. In this embodiment, the transmission signal is on layer 20, the receiving signal is on layer 22, with 8.7 millimeter spacing between them.

FIGS. 12 and 13 are graphs of signal integrity performance between a related art PCB and an example embodiment of a PCB according to the disclosed techniques, respectively. In particular, FIGS. 12 and 13 relate to the NEXT signal crosstalk performance.

In FIG. 12, the crosstalk performance of NEXT signals in decibels associated with related art PCB 300 is illustrated. In FIG. 12, graph 700 includes a line 710 that represents the performance associated with differential pair 314 (D1), a line 720 that represents the performance associated with differential pair 316 (D2), and a line 730 that represents the performance associated with differential pair 318 (D3). Graph 700 also includes a line 740 that represents PS-NEXT.

As shown, graph 700 includes labels of data points at different frequencies. At 28 GHZ, the measured NEXT for line 710 is −57.59 dB, the measured NEXT for line 720 is −44.25 dB, the measured NEXT for line 730 is −56.82 dB, and the measured NEXT for line 740 is −43.83 dB. At 56 GHz, the measured NEXT for line 710 is −60.50 dB, the measured NEXT for line 720 is −37.37 dB, the measured NEXT for line 730 is −61.54 dB, and the measured NEXT for line 740 is −37.33 dB. Crosstalk performance for PCB 300 is very poor, as shown in graph 700, because a large quantity of ground VIAs cut up the power plane and introduce micro cavity resonances impact on crosstalk signal performance.

In FIG. 13, the crosstalk performance of NEXT signals in decibels associated with PCB 500 is illustrated. In FIG. 13, graph 800 includes a line 810 that represents the performance associated with differential pair 514 (D1), a line 820 that represents the performance associated with differential pair 516 (D2), and a line 830 that represents the performance associated with differential pair 518 (D3). Graph 800 also includes a line 840 that represents PS-NEXT.

As shown, graph 800 includes labels of data points at different frequencies. At 28 GHZ, the measured NEXT for line 810 is −99.46 dB, the measured NEXT for line 820 is −66.18 dB, the measured NEXT for line 830 is −101.69 dB, and the measured NEXT for line 840 is −66.18 dB. At 56 GHz, the measured NEXT for line 810 is −93.89 dB, the measured NEXT for line 820 is −72.04 dB, the measured NEXT for line 830 is −96.24 dB, and the measured NEXT for line 840 is −72.08 dB. The PS-NEXT improvement between line 740 in graph 700 and line 840 in graph 800 is from −37 dB to −72 dB, which is around a 35 dB improvement. Crosstalk performance for PCB 500, and in particular, NEXT crosstalk, is better than the NEXT crosstalk performance for PCB 300 because the NEXT crosstalk between differential pairs is improved or reduced. For a 224 Gbps design, the NEXT crosstalk performance target is less than or equal to −55 dB at 56 GHz.

FIGS. 14 and 15 are graphs of signal integrity performance between a related art PCB and an example embodiment of a PCB according to the disclosed techniques, respectively. In particular, FIGS. 14 and 15 relate to the FEXT signal crosstalk performance.

In FIG. 14, the crosstalk performance of FEXT signals in decibels associated with related art PCB 400 is illustrated. In FIG. 14, graph 900 includes a line 910 that represents the performance associated with differential pair 414 (D1) and differential pair 416 (D2), a line 920 that represents the performance associated with differential pair 418 (D3) and differential pair 416 (D2), a line 930 that represents the performance associated with differential pair 420 (D4) and differential pair 416 (D2), and a line 940 that represents the performance associated with differential pair 422 (D5) and differential pair 416 (D2). Graph 900 also includes a line 950 that represents PS-FEXT.

As shown, graph 900 includes labels of data points at different frequencies. At 28 GHZ, the measured FEXT for line 910 is −62.73 dB, the measured FEXT for line 920 is −62.79 dB, the measured FEXT for line 930 is −33.61 dB, the measured FEXT for line 940 is −59.02 dB, and the measured FEXT for line 950 is −30.58. At 56 GHZ, the measured FEXT for line 910 is −42.55 dB, the measured FEXT for line 920 is −42.78 dB, the measured FEXT for line 930 is −29.91 dB, the measured FEXT for line 940 is −37.80 dB, and the measured FEXT for line 950 is −26.05. Crosstalk performance for related art PCB 400 is very poor, as shown in graph 900, because a large quantity of ground VIAs cut up the power plane and introduce micro cavity resonances impact on crosstalk signal performance.

In FIG. 15, the crosstalk performance of FEXT signals in decibels associated with PCB 600 is illustrated. In FIG. 15, graph 1000 includes a line 1010 that represents the performance associated with differential pair 614 (D1) and differential pair 616 (D2), a line 1020 that represents the performance associated with differential pair 618 (D3) and differential pair 616 (D2), a line 1030 that represents the performance associated with differential pair 620 (D4) and differential pair 616 (D2), and a line 1040 that represents the performance associated with differential pair 622 (D5) and differential pair 616 (D2). Graph 1000 also includes a line 1050 that represents PS-FEXT.

As shown, graph 1000 includes labels of data points at different frequencies. At 28 GHz, the measured FEXT for line 1010 is −52.22 dB, the measured FEXT for line 1020 is −52.14 dB, the measured FEXT for line 1030 is −47.26 dB, the measured FEXT for line 1040 is −56.23 dB, and the measured FEXT for line 1050 is −42.64. At 56 GHz, the measured FEXT for line 1010 is −45.92 dB, the measured FEXT for line 1020 is −45.85 dB, the measured FEXT for line 1030 is −48.09 dB, the measured FEXT for line 1040 is −46.22 dB, and the measured FEXT for line 1050 is −39.01. The PS-FEXT improvement between line 950 in graph 900 and line 1050 in graph 1000 is from −26 dB to −39 dB, which is around a 13 dB improvement. Crosstalk performance for PCB 600, and in particular, FEXT crosstalk, is better than the FEXT crosstalk performance for PCB 400 because the FEXT crosstalk between differential pairs is improved or reduced. For a 224 Gbps design, the FEXT crosstalk performance target is less than or equal to −40 dB at 56 GHz.

In summary, the advantages of the example embodiments of circuit boards according to the disclosed techniques relate to the multi-lamination structure as compared to a related art one-lamination structure. The advantages include: signal integrity crosstalk performance is excellent and permits the use of 224 Gbps signals in the PCB; an overall low cost with good signal integrity performance for 224 Gbps and 112 Gbps systems (the quantities of layers is reduced and a lower PCB matrix process can be used); improved routing areas for a high density PCB board due to fewer cutouts and openings in the layers; improved power integrity; a PCB manufacturing process with only two additional laminations is used to make the PCB; a decreased power noise coupling to a signal as there are no power plane shapes or VIAs near the signals; and increased long-term reliability using a lower aspect ratio for the drilling of the VIAs.

In some aspects, the techniques described herein relate to a printed circuit board, comprising: a first group of layers laminated together, the first group of layers being directed to high speed signal routing; and a second group of layers laminated together, the second group of layers being directed to delivering power, wherein when the second group of layers are laminated to the first group of layers, the first group of layers and the second group of layers collectively form a multi-lamination structure.

In some aspects, the techniques described herein relate to the first group of layers is coupled to the second group of layers through a lamination process after the first group of layers is laminated together and the second group of layers is laminated together.

In some aspects, the techniques described herein relate to the first group of layers located on top of the second group of layers.

In some aspects, the techniques described herein relate to the first group of layers having a ball grid array area, the printed circuit board has a through hole that is used for a power connection at the ball grid array area, and the through hole extends through the first group of layers and through the second group of layers.

In some aspects, the techniques described herein relate to the multi-lamination structure eliminates power planes introduced by micro cavity resonance.

In some aspects, the techniques described herein relate to the high speed signal routing is separated from a power delivery plane.

In some aspects, the techniques described herein relate to the first group of layers including 32 layers, and the second group of layers includes 12 layers.

In some aspects, the techniques described herein relate to a printed circuit board, comprising a first plurality of layers, the first plurality of layers being laminated together to form a first lamination structure, the first lamination structure being directed to high speed signal routing, and a second plurality of layers, the second plurality of layers being laminated together to form a second lamination structure, the second lamination structure being directed to delivering power for the printed circuit board, wherein when the second lamination structure is laminated to the first lamination structure, the first lamination structure and the second lamination structure collectively form a multi-lamination structure.

In some aspects, the techniques described herein relate to the first lamination structure is coupled to the second lamination structure through a lamination process after the first lamination structure is formed and after the second lamination structure is formed.

In some aspects, the techniques described herein relate to the first lamination structure being located on top of the second lamination structure.

In some aspects, the techniques described herein relate to the first lamination structure has a ball grid array area, each of the first lamination structure and the second lamination structure has a hole extending therethrough that is used for a power connection at the ball grid array area.

In some aspects, the techniques described herein relate to the multi-lamination structure eliminates power planes introduced by micro cavity resonance.

In some aspects, the techniques described herein relate to the high speed signal routing is separated from a power delivery plane.

In some aspects, the techniques described herein relate to a quantity of layers in the first lamination structure is greater than a quantity of layers in the second lamination structure.

In some aspects, the techniques described herein relate to a method of manufacturing a printed circuit board (PCB), comprising the steps of selecting a first plurality of layers, laminating the first plurality of layers together to form a first lamination structure, selecting a second plurality of layers, laminating the second plurality of layers together to form a second lamination structure, and laminating the first lamination structure and the second lamination structure together, wherein the first plurality of layers is directed to high speed signal routing, the second plurality of layers is directed to delivering power for the PCB, and the first lamination structure and the second lamination structure collectively form a multi-lamination structure.

In some aspects, the techniques described herein relate to the step of positioning the first lamination structure on top of the second lamination structure prior to the step of laminating the first lamination structure and the second lamination structure together.

In some aspects, the techniques described herein relate to the first plurality of layers having a ball grid array area, and each of the first plurality of layers and the second plurality of layers has a through hole that is used for a power connection at the ball grid array area.

In some aspects, the techniques described herein relate to the multi-lamination structure eliminating power planes introduced by micro cavity resonance.

In some aspects, the techniques described herein relate to the high speed signal routing separated from a power delivery plane.

In some aspects, the techniques described herein relate to the first plurality of layers including 32 layers, and the second plurality of layers includes 12 layers.

### Variations and Implementations

Note that in this Specification, references to various features (e.g., elements, structures, nodes, modules, components, engines, logic, steps, operations, functions, characteristics, etc.) included in “one embodiment,” “example embodiment,” “an embodiment,” “another embodiment,” “certain embodiments,” “some embodiments,” “various embodiments,” “other embodiments,” “alternative embodiment,” and the like are intended to mean that any such features are included in one or more embodiments of the present disclosure, but may or may not necessarily be combined in the same embodiments.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase “at least one of,” “one or more of,” “and/or,” variations thereof, or the like are open-ended expressions that are both conjunctive and disjunctive in operation for any and all possible combination of the associated listed items. For example, each of the expressions “at least one of X, Y and Z,” “at least one of X, Y or Z,” “one or more of X, Y and Z,” “one or more of X, Y or Z” and “X, Y and/or Z” can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms “first,” “second,” “third,” etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, “first X” and “second X” are intended to designate two “X” elements that are not necessarily limited by any order, rank, importance, temporal sequence, or hierarchy of the two elements. Further as referred to herein, “at least one of” and “one or more of” can be represented using the “(s)” nomenclature (e.g., one or more element(s)).

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. A printed circuit board, comprising:
a first group of layers laminated together, the first group of layers being directed to high speed signal routing; and
a second group of layers laminated together, the second group of layers being directed to delivering power, wherein when the second group of layers are laminated to the first group of layers, the first group of layers and the second group of layers collectively form a multi-lamination structure.

2. The printed circuit board of claim 1, wherein the first group of layers is coupled to the second group of layers through a lamination process after the first group of layers is laminated together and the second group of layers is laminated together.

3. The printed circuit board of claim 1, wherein the first group of layers is located on top of the second group of layers.

4. The printed circuit board of claim 1, wherein the first group of layers has a ball grid array area, the printed circuit board has a through hole that is used for a power connection at the ball grid array area, and the through hole extends through the first group of layers and through the second group of layers.

5. The printed circuit board of claim 1, wherein the multi-lamination structure eliminates power planes introduced by micro cavity resonance.

6. The printed circuit board of claim 1, wherein the high speed signal routing is separated from a power delivery plane.

7. The printed circuit board of claim 1, wherein the first group of layers includes 32 layers, and the second group of layers includes 12 layers.

8. A printed circuit board, comprising:
a first plurality of layers, the first plurality of layers being laminated together to form a first lamination structure, the first lamination structure being directed to high speed signal routing; and
a second plurality of layers, the second plurality of layers being laminated together to form a second lamination structure, the second lamination structure being directed to delivering power for the printed circuit board, wherein when the second lamination structure is laminated to the first lamination structure, the first lamination structure and the second lamination structure collectively form a multi-lamination structure.

9. The printed circuit board of claim 8, wherein the first lamination structure is coupled to the second lamination structure through a lamination process after the first lamination structure is formed and after the second lamination structure is formed.

10. The printed circuit board of claim 8, wherein the first lamination structure is located on top of the second lamination structure.

11. The printed circuit board of claim 8, wherein the first lamination structure has a ball grid array area, each of the first lamination structure and the second lamination structure has a hole extending therethrough that is used for a power connection at the ball grid array area.

12. The printed circuit board of claim 8, wherein the multi-lamination structure eliminates power planes introduced by micro cavity resonance.

13. The printed circuit board of claim 8, wherein the high speed signal routing is separated from a power delivery plane.

14. The printed circuit board of claim 8, wherein a quantity of layers in the first lamination structure is greater than a quantity of layers in the second lamination structure.

15. A method of manufacturing a printed circuit board (PCB), comprising:
selecting a first plurality of layers;
laminating the first plurality of layers together to form a first lamination structure;
selecting a second plurality of layers;
laminating the second plurality of layers together to form a second lamination structure; and
laminating the first lamination structure and the second lamination structure together, wherein the first plurality of layers is directed to high speed signal routing, the second plurality of layers is directed to delivering power for the PCB, and the first lamination structure and the second lamination structure collectively form a multi-lamination structure.

16. The method of claim 15, further comprising:
positioning the first lamination structure on top of the second lamination structure prior to the step of laminating the first lamination structure and the second lamination structure together.

17. The method of claim 15, wherein the first plurality of layers has a ball grid array area, and each of the first plurality of layers and the second plurality of layers has a through hole that is used for a power connection at the ball grid array area.

18. The method of claim 15, wherein the multi-lamination structure eliminates power planes introduced by micro cavity resonance.

19. The method of claim 15, wherein the high speed signal routing is separated from a power delivery plane.

20. The method of claim 15, wherein the first plurality of layers includes 32 layers, and the second plurality of layers includes 12 layers.
